(19) United States
(12) Patent Application Publication
(10) Pub. No.: US 2019/0335612 A1
(43) Pub. Date: Oct. 31, 2019

(54) Fluid Spray System to Cool Telecommunications Equipment

(71) Applicant: Parallel Wireless, Inc., Nashua, NH (US)

(72) Inventor: Christopher Simmonds, Andover, MA (US)

(21) Appl. No.: 16/399,280

(22) Filed: Apr. 30, 2019

Related U.S. Application Data
(60) Provisional application No. 62/664,676, filed on Apr. 30, 2018.

(51) Int. Cl. H05K 7/20; F25B 19/00; H01Q 1/02

(52) U.S. Cl. CPC H05K 7/20136; H01Q 1/02; H05K 7/20272; F25B 19/00

(57) ABSTRACT

A system is disclosed for cooling telecommunications equipment. The system includes a nozzle disposed proximate a piece of telecommunication equipment to be cooled and a fluid conduit in fluid communication with the nozzle. A fluid supply is coupled to the fluid conduit and provides fluid to the fluid nozzle. A nozzle control system is coupled to the nozzle and configured to actuate the nozzle to cause fluid to emerge from the nozzle, thereby providing a fluid mist to cool the air surrounding at least a part of the telecommunication equipment.

### CROSS-REFERENCE TO RELATED APPLICATIONS

This application claims priority under 35 U.S.C. § 119(e) to U.S. Provisional Pat. App. No. 62/664,676, filed Apr. 30, 2019, titled “Water Spray System to Cool Telecoms Equipment” which is also hereby incorporated by reference in its entirety for all purposes. This application also hereby incorporates by reference, for all purposes, each of the following U.S. Patent Application Publications in their entirety: US20170013513A1; US20170026845A1; US20170055186A1; US20170070436A1; US20170077979A1; US20170019375A1; US20170111482A1; US20170048710A1; US20170127409A1; US20170064621A1; US20170202006A1; US20170238278A1; US20170171828A1; US20170181119A1; US20170273134A1; US20170272330A1; US20170208560A1; US20170288813A1; US20170295510A1; US20170303163A1; and US20170257133A1. This application also hereby incorporates by reference U.S. Pat. No. 8,879,416, “Heterogeneous Mesh Network and Multi-RAT Node Used Therein,” filed May 8, 2013; U.S. Pat. No. 9,113,352, “Heterogeneous Self-Organizing Network for Access and Backhaul,” filed Sep. 12, 2013; U.S. Pat. No. 8,867,418, “Methods of Incorporating an Ad Hoc Cellular Network Into a Fixed Cellular Network,” filed Feb. 18, 2014; U.S. patent application Ser. No. 14/034,915, “Dynamic Multi-Access Wireless Network Virtualization,” filed Sep. 24, 2013; U.S. patent application Ser. No. 14/289,821, “Method of Connecting Security Gateway to Mesh Network,” filed May 29, 2014; U.S. patent application Ser. No. 14/500,989, “Adjusting Transmit Power Across a Network,” filed Sep. 29, 2014; U.S. patent application Ser. No. 14/506,587, “Multicast and Broadcast Services Over a Mesh Network,” filed Oct. 3, 2014; U.S. patent application Ser. No. 14/510,074, “Parameter Optimization and Event Prediction Based on Cell Heuristics,” filed Oct. 8, 2014, U.S. patent application Ser. No. 14/642,544, “Federated X2 Gateway,” filed Mar. 9, 2015, and U.S. patent application Ser. No. 14/936,267, “Self-Calibrating and Self-Adjusting Network,” filed Nov. 9, 2015; U.S. patent application Ser. No. 15/607,425, “End-to-End Prioritization for Mobile Base Station,” filed May 26, 2017; U.S. patent application Ser. No. 15/803,737, “Traffic Shaping and End-to-End Prioritization,” filed Nov. 27, 2017, each in its entirety for all purposes, having attorney docket numbers PWS-71700US01, US02, US03, 71710US01, 71721US01, 71729US01, 71730US01, 71731US01, 71756US01, 71775US01, 71865US01, and 71866US01, respectively. This document also hereby incorporates by reference U.S. Pat. Nos. 9,107,092, 8,867,418, and 9,232,547 in their entirety. This document also hereby incorporates by reference U.S. patent application Ser. Nos. 14/822,839, 15/828,427, U.S. Pat. App. Pub. Nos. US20170273134A1, US20170127409A1 in their entirety. The purposes for the above incorporations by reference include at least to provide detailed information about the features and functionality of the Parallel Wireless CWS (RAN) and HNG (coordinator) products.

### BACKGROUND

Telecommunication equipment may operate in a wide variety of locations and environment. In some environments a piece of telecommunication equipment may have a problem regarding heat, which can affect operation of the telecommunication equipment. For example, an air temperature of over 55° C. in a desert, plus direct sunlight, causes heat buildup within the telecommunication equipment. Radiant energy of sun is strongest at noon, but greatest heating occurs when an area of telecommunication system that is affected by solar heating reaches a maximum temperature. Sun-shade may not help with radiant heating of side of the telecommunications system, only the top. The power used by the telecommunication system components (power amplifiers, processors, baseband, etc.) also increases heat. Typically, air cooling may be used to cool the telecommunication equipment, however this may not always be sufficient to provide a desired amount of cooling.

### SUMMARY OF THE INVENTION

The present spray system to cool telecommunication equipment relates generally to cooling telecommunication equipment, and in particular, to a fluid misting system to cool air surrounding at least a part of a telecommunications device.

In a first embodiment, a system is disclosed for cooling telecommunication equipment. The system includes a nozzle disposed proximate a piece of telecommunication equipment to be cooled and a fluid conduit in fluid communication with the nozzle. The system further includes a fluid supply coupled to the fluid conduit and providing fluid to the fluid nozzle, and a nozzle control system configured to actuate the nozzle to cause fluid to emerge from the nozzle, thereby providing a fluid mist to cool the air surrounding at least a part of the telecommunication equipment.

In a second embodiment, a system for cooling of telecommunications equipment is disclosed, comprising: A ring of tubing, positioned below at least one radio antenna and above a radio device to be cooled, the ring of tubing and the at least one radio antenna and the radio device to be cooled being affixed to a telecommunications mast; A sprinkler physically coupled to the ring of tubing and configured to receive water from the ring of tubing; A sprinkler control system configured to actuate the sprinkler to cause water to emerge from the sprinkler, thereby creating mist in the vicinity of the radio device to be cooled; and A water supply coupled to the ring of tubing and located in a location protected from solar heating.

Other aspects and advantages of the invention will become apparent from the following drawings, detailed description, and claims, all of which illustrate the principles of the invention, by way of example only.

### BRIEF DESCRIPTION OF THE DRAWINGS

A more complete appreciation of the invention and many attendant advantages thereof will be readily obtained as the same becomes better understood by reference to the following detailed description when considered in connection with the accompanying drawings. In the drawings, like reference characters generally refer to the same parts throughout the different views. Further, the drawings are not necessarily to scale, with emphasis instead generally being placed upon illustrating the principles of the invention.

FIG. 1 depicts a diagram of a fluid spray system for cooling telecommunications equipment, in accordance with some embodiments.

FIG. 2 depicts an image of a spray nozzle included as part of a fluid spray system for cooling telecommunications equipment, in accordance with some embodiments.

FIG. 3. is an enhanced eNodeB for performing the actions described herein, in accordance with some embodiments.

### DETAILED DESCRIPTION

In reference to the below disclosure, a water-tight telecommunications equipment is contemplated. For example, some base stations are IP68-rated: dust-tight, no ingress of dust for 2-8 hours; protection against immersion under pressure for long periods; no higher rating exists. They are designed to be water-tight for use in outdoor conditions, including rain, mist, sleet, hail, salt mist, pressurized hoses and are also typically designed to be air-cooled. Since they are air-cooled, desert deployments require a structure or enclosure with air conditioning, such that the water- and dust-tight characteristics of the equipment are underutilized.

A fluid spray system for cooling telecommunication equipment is disclosed. Fluid (either gas, liquid or a combination thereof) misting will cool the air surrounding at least a portion of the telecommunications equipment, reducing heating. The use of fluid misting will be advantageous for several reasons. The cooling of the air reduces heating. Cooling of the unit directly results in evaporative cooling as the fluid evaporates off of the unit. As well, mist sprinklers can be oriented to focus on the main face, or other localized areas which experience greater heating, and not to focus on areas like antennas that do not get hot. This may be accomplished by way of an arrangement of mist nozzles. While the present description refers to water used for cooling, it should be appreciated that this is for explanation purposes only and that any fluid (gas or liquid) could be used.

The presently described fluid spray system provides advantages over the typical approach of electrically-driven air conditioning. A typical central air conditioner uses 3-5 kilowatts of power every hour, so about 75 gallons of water has been used to run the air conditioner for one hour. In contrast to air conditioners, a small water pump uses around 250 watts (so only about ¼ a kilowatt) of electricity per hour. If you have a 10 ft×10 ft deck or patio, you'll typically use around 10 nozzles (1 nozzle every 3 feet for 30 ft of tubing around the perimeter of the area). The pump and 1 gallon per hour (GPH) nozzles will use roughly 16-¼ gallons of water every hour, which is significantly less than running a central air conditioner for an hour.

The presently described fluid spray system provides advantage in terms of efficiency. The efficiency of the telecommunications equipment will be improved by lowering the temperature (hot devices are more resistive and draw more current). This can either save additional power consumption for the same Radio Frequency (RF) power (same RF power output for coverage at less consumption), or may allow the telecommunication equipment to operate in higher than rated ambient and radiant (solar) temperature environments without having to back power off—i.e. maintains cell coverage, no need to reduce the RF power to compensate for the thermal load vs. maximum for the product, which would otherwise result in reduced coverage.

In some embodiments, the presently described fluid spray system can be driven by a solar array—as the conditions for use of this are when there is strong direct sunlight. Water or other fluid may improve or maintain the radio efficiency over time as it will remove dust and dirt build-up that will have degraded the thermal transfer properties of the product. A one or two nozzle system could be used. A thermal switch for activating the fluid spray system, or switching even controlled by the telecommunications equipment through the alarms port (if output available), or the second ethernet port, or independent based on temperature if not controlled by the radio.

In some embodiments, water may be extracted from air, e.g., using a large dew catch tarpaulin, or via new methods (http://news.mit.edu/2018/field-tests-device-harvests-water-desert-air-0322). The fluid may be stored in a below-ground tank to avoid radiant heating of the fluid tank and of the fluid stored therein.

In some embodiments, the nozzles would be microcontroller-controlled, could be controlled by Internet of Things (IoT) devices, or wired or Wi-Fi, or connected to a base station as a User equipment (UE), or via a serial port. A fan could be integrated to move the fluid around (not needed for airflow over unit though, just for the fluid). A solar array could power a pump for the fluid. The fluid spray system could be used to cool the exterior of a cabinet, in cases that telecommunications equipment is placed inside of an above-ground cabinet.

In some embodiments the misting or other operation of the fluid spray system could be software-controlled, for example by software on a purpose-built microcontroller coupled to the system, by software on the base station, by a controller or in a mesh network of the base station, or for example connected via serial port or low-bandwidth wireless. In some embodiments the system could controlled by self-organizing network (SON) or central controller, as further described by US20150257051, hereby incorporated by reference, which may be remote and/or connected over the Internet. In some embodiments the system could controlled manually or automatically by remote HQ/OSS/management console. In some embodiments, the system could be controlled by a cellular base station, such as a Parallel Wireless Converged Wireless System (CWS), or by a management gateway, such as a Parallel Wireless HetNet Gateway (HNG). In some embodiments, the system could be controlled based on time of day; Radio or Central Processor Unit (CPU) usage, or by a predicted radio/CPU usage. In some embodiments the system could controlled based on power usage, including predicted power usage. In some embodiments, the power usage could be predicted by the HetNet Gateway (HNG) or controller node and sent to the base station. In some embodiments, the power usage could be measured by the base station and sent to the HNG. In some embodiments the system could be operated based on measured outdoor temperature or unit temperature, or big data or analytics or observed/predicted statistical patterns. Any systems and methods for prediction could use the systems, methods described in US20160135132, hereby incorporated by reference.

In some embodiments the system could be implemented on a unit that is IPXL IP66 rated or higher, or on a unit that has been treated with conformal coatings on the electronics (i.e., on the circuit boards within the unit, to provide additional protection against moisture even when moisture enters the unit).

The telecommunication equipment may be mounted on a mast, a wall or other structure. Accordingly, a ring of nozzles could be supported around one piece of telecommunications equipment, or multiple pieces of telecommunications equipment, or a nozzle on a straight pole pointed at the piece of telecommunications equipment. The nozzles may or may not be specifically oriented toward the piece of telecommunications equipment, as given enough nozzles, there is no need to mist directly. A cooling device could be affixed to the feed line to cool the fluid before being emitted by the nozzles.

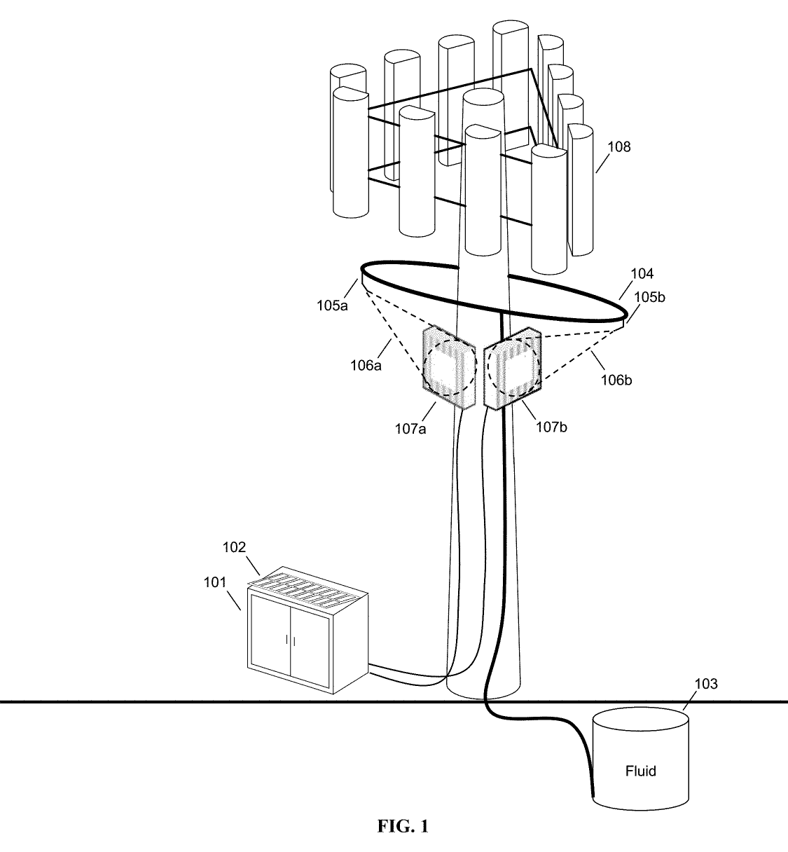

FIG. 1 is a diagram of an example cooling system for telecommunications equipment. In this example, a telecommunications mast is shown having a radio antenna 108 disposed thereon. A fluid conduit 104 is located below the radio antenna and above the piece of telecommunication equipment 107a and 107b to be cooled. The fluid conduit 104 and the radio antenna 108 and the pieces of telecommunication equipment 107a and 107b to be cooled are in mechanical communication with the telecommunications mast. Also shown are nozzles 105a and 105b disposed proximate the pieces of telecommunication equipment 107a and 107b to be cooled. The fluid conduit 104 is in fluid communication with the nozzles 105a and 105b. A fluid supply 103 is coupled to the fluid conduit 104 and provides fluid to the fluid nozzles 105a and 105b. A nozzle control system (not shown) is configured to actuate the nozzles to cause fluid to emerge from the nozzle, thereby providing a fluid mist 106a and 106b to cool the air surrounding at least a part of the telecommunication equipment 107a and 107b.

The fluid may comprise a gas or a liquid (e.g. water). In some embodiments, the telecommunication equipment comprises a base station. In some embodiments, the system may further include a fluid pump disposed between the fluid supply and the fluid conduit. In some embodiments, the fluid pump may be solar powered by solar array 102 mounted on cabinet 101. In some embodiments, the fluid supply comprises a fluid storage tank. In some embodiments the fluid storage tank is disposed underground.

In some embodiments, the nozzle control system comprises a microcontroller based control system, a base station based control system or an Internet of things (IoT) device based control system.

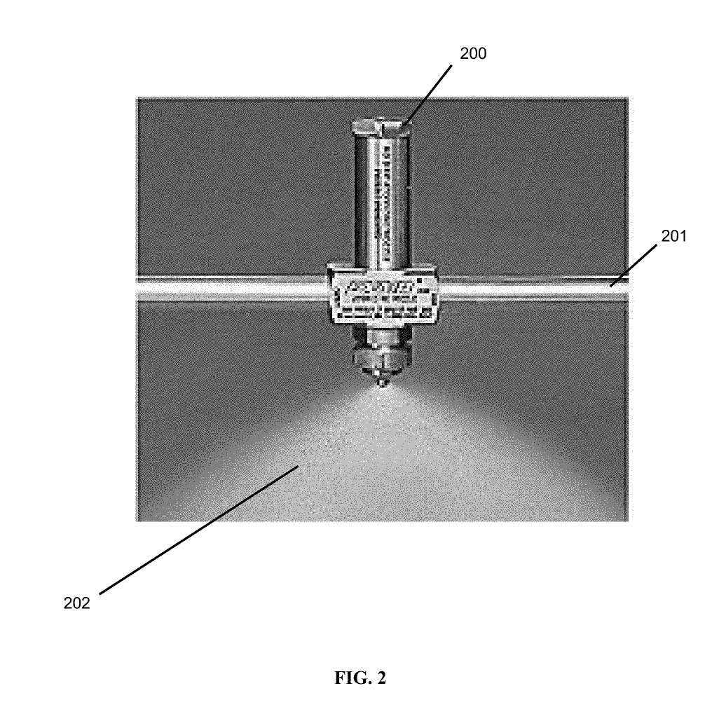

FIG. 2 is a picture of an example nozzle providing mist. A nozzle 200 is in fluid communication with a fluid conduit 201. The nozzle 200 produces a mist 202 to cool the air surrounding the piece of telecommunications equipment. In some embodiments, the shape and volume of the mist may be adjustable.

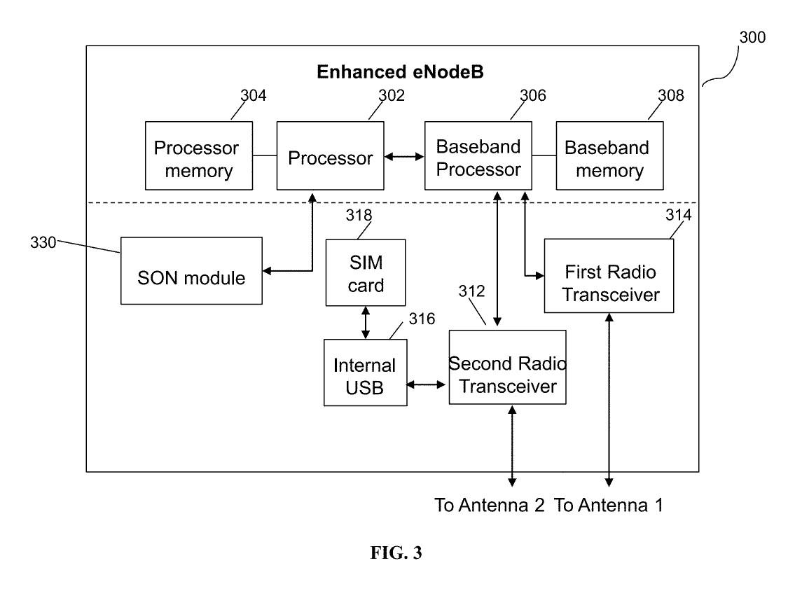

FIG. 3 is a schematic diagram of an enhanced eNodeB, in accordance with some embodiments. Enhanced eNodeB 300 may include processor 301, processor memory 302 in communication with the processor, baseband processor 303. Enhanced eNodeB 300 may also include Wi-Fi access transceiver 304 with access side interface 315, and LTE access transceiver 305 with access side interface 314 and thereby connecting to user equipments (not shown in the figure). Enhanced eNodeB 300 may also include wired backhaul 306 with wired backhaul interface 310, 3G backhaul 307 with 3G backhaul interface 311, LTE backhaul 308 with LTE backhaul interface 312, and Wi-Fi backhaul 309 with Wi-Fi backhaul interface 313. Enhanced eNodeB provides backhaul connectivity via backhaul interfaces 310, 311, 312, and 313 to user equipments connected to the enhanced eNodeB via access interfaces 314 and 315. As shown in the FIG. 3, LTE access transceiver 305 and Wi-Fi access transceiver are further in communication with baseband processor 303 that is also in communication with processor 301.

Processor 301 and baseband processor 303 are in communication with one another. Processor 301 may perform routing functions, and may determine if/when a switch in network configuration is needed. Baseband processor 303 may generate and receive radio signals for both wi-fi access transceiver 304 and LTE access transceiver 305, based on instructions from processor 301. In some embodiments, processors 301 and baseband processor 303 may be on the same physical logic board. In other embodiments, they may be on separate logic boards.

The LTE access transceiver 305 may be a radio transceiver capable of providing LTE eNodeB functionality, and may be capable of higher power and multi-channel OFDMA. The LTE backhaul 308 may be a radio transceiver capable of providing LTE UE functionality. Both 305 and 308 are capable of receiving and transmitting on one or more LTE bands. In some embodiments, either or both of transceivers 305 and 308 may be capable of providing both LTE eNodeB and LTE UE functionality. Transceivers 305 and 308 may be coupled to processor 301 via baseband processor 303. In addition, wired backhaul 306 coupled to processor 301 may provide backhaul connectivity to other 3G femto base station via wired Ethernet interface 310. 3G backhaul 307 coupled to processor may provide 3G wireless backhaul connectivity.

Wired backhaul 306, or wireless backhaul 309, or any combination of backhaul, may be used. Wired backhaul 306 may be an Ethernet-based backhaul (including Gigabit Ethernet), or a fiber-optic backhaul connection, or a cable-based backhaul connection, in some embodiments. Additionally, wireless backhaul 309 may be provided in addition to 3G backhaul 307 and LTE backhaul 308, which may be Wi-Fi 302.11a/b/g/n/ac/ad/ah, Bluetooth, ZigBee, microwave (including line-of-sight microwave), or another wireless backhaul connection. Any of the wired and wireless connections may be used for either access or backhaul, according to identified network conditions and needs, and may be under the control of processor 302 for reconfiguration.

Other elements and/or modules may also be included, such as a home eNodeB, a local gateway (LGW), a self-organizing network (SON) module, or another module. Additional radio amplifiers, radio transceivers and/or wired network connections may also be included.

Processor 301 may identify the appropriate network configuration and may perform execute instructions stored in processor memory 302 for admission control, application layer processing 301a, routing and shaping 301b of packets from one network interface to another accordingly. Processor 301 manages internal policy state and monitoring, determines local congestion, and communicates with the coordinating node. Processor 301 may use memory 302, in particular to store a routing table to be used for routing packets. Baseband processor 303 may perform operations to generate the radio frequency signals for transmission or retransmission by transceivers such as 304, 305, 307, 308, 309. Baseband processor 303 may also perform operations to decode signals received by transceivers 304, 305, 307, 308, 309. Baseband processor 306 may use memory 302 to perform these tasks. Further, processor 301 may perform tagging at tagger 301d that may be part of IP protocol functionality 301c in communication with application layer 301a. Network interface drivers 301e may send and receive messages over backhaul interfaces 310, 311, 312, 313 via 306, 307, 308, 309 respectively.

In operation, packets may be received from access transceivers 304, 305 and may be processed by processor 301 to determine what type of tagging is required. The packets may be tagged by tagger 301d in conjunction with program logic in application 301a, which identifies the type of traffic. Prioritization is performed at routing/shaping layer 301b, which issues instructions to IP protocol stack 301c to enqueue packets for the backhaul link(s), and the queued packets are sent out via network interface driver 301e to backhaul interfaces 306, 307, 308, 309. Admission control is handled at application level 301a (the RAN PHY is the application in this case).

The foregoing discussion discloses and describes merely exemplary embodiments of the present invention. As will be understood by those skilled in the art, the present invention may be embodied in other specific forms without departing from the spirit or essential characteristics thereof. Various components in the devices described herein may be added, removed, or substituted with those having the same or similar functionality. Various steps as described in the figures and specification may be added or removed from the processes described herein, and the steps described may be performed in an alternative order, consistent with the spirit of the invention. Accordingly, the disclosure of the present invention is intended to be illustrative, but not limiting of the scope of the invention, as well as other claims. The disclosure, including any readily discernible variants of the teachings herein, defines, in part, the scope of the foregoing claim terminology.

It is understood that any specific order or hierarchy of steps in the processes disclosed is an illustration of example approaches. Based upon design preferences, it is understood that the specific order or hierarchy of steps in the processes may be rearranged, or that all illustrated steps be performed. Some of the steps may be performed simultaneously. For example, in certain circumstances, multitasking and parallel processing may be advantageous. Moreover, the separation of various system components illustrated above should not be understood as requiring such separation, and it should be understood that the described program components and system can generally be integrated together in a single software product or packaged into multiple software products.

The above-described features and applications can be implemented as software processes that are specified as a set of instructions recorded on a computer-readable storage medium (also referred to as computer readable medium). When these instructions are executed by one or more processing unit(s) (e.g. one or more processors, cores of processors, or other processing units), they cause the processing unit(s) to perform the actions indicated in the instructions. Examples of computer readable media include, but are not limited to, CD-ROMs, flash drives, hard drives, RAM chips, EPROMs, etc. The computer-readable media does not include carrier waves and electronic signals passing wirelessly or wired connections. Code may be written in any combination of programming languages or machine-readable data formats, each suitable to its particular application, including but not limited to: C, C++, Java, Python, Ruby, R, Lua, Lisp, Scala, JSON, JavaScript, YAML, XML, HTML, etc. Services may be RESTful and may be implemented using generic hooks, including over HTTP, HTTPS, SCTP, IP, TCP, JSON, JavaScript, etc., as well as via inter-process communication on one or more real or virtual machines or containers, e.g., IPC, shared memory, shared filesystem, UNIX pipes and the like. A Linux or POSIX environment may be used. Containers may be Docker, Jetty, Tomcat, Wildfy, Springboot, LXD, unikernels, OpenVZ, RKT, Windows Server, Hyper-V, or any other type of container, or may be, in some embodiments, virtual machines or images, etc. Network access may be relied upon or may be avoided, in various embodiments. A networking fabric may be provided among the different containers, in some embodiments. As is well-known, the benefit of using cloud infrastructure is that it is simple to mix heterogeneous resources and to scale services up or down based on load and desired performance.

In the specification, the term “software” is meant to include firmware residing in read-only memory or applications stored in magnetic storage or flash storage, for example, a solid-state drive, which can be read into memory for processing by a processor. Also, in some implementations, multiple software technologies can be implemented as sub-parts of a larger program while remaining distinct software technologies. In some implementations, multiple software technologies can also be implemented as separate programs. Finally, any combination of separate programs that together implement a software technology described here is within the scope of the subject technology. In some implementations, the software programs, when installed to operate on one or more electronics systems, define one or more specific machine implementations that execute and perform the operations of the software programs.

A computer program (also known as program, software, software application, script, or code) can be written in any form of programming language, including compiled or interpreted languages, declarative or procedural languages, and it can be deployed in any form, including as a standalone program or as a module, component, subroutine, object, or another unit suitable for use in a computing environment. A computer program may, but need not correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

These functions described above can be implemented in digital electronic circuitry, in computer software, hardware, or firmware. The techniques can be implemented using one or more computer program products. Programmable processors and computers can be included in or packaged as mobile devices. The process and logic flows can be performed by one or more programmable processors and by one or more programmable logic circuitry. General and special purpose computing devices and storage devices can be interconnected through communication networks.

Some implementations include electronic components, for example microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), readable compact discs (CD-R), rewritable compact discs (CD-RW), read-only digital versatile discs (e.g., DVD-ROM, dual-layer DVD-ROM), a variety of recordable/rewritable DVDs (e.g. DVD-RAM, DVD−RW, DVD+RW, etc.), flash memory (e.g., SD cards, mini-SD cards, micro-SD cards, etc.), magnetic or solid-state hard drives, read-only and recordable Blu-Ray® discs, ultra-density optical discs, any other optical or magnetic media, and floppy disks. The computer-readable media can store a computer program that is executed by at least one processing unit and includes sets of instructions for performing various operations. Examples of computer programs or computer code include machine code, for example is produced by a compiler, and files including higher-level code that are executed by a computer, an electronic component, or a microprocessor using an interpreter.

While the above discussion primarily refers to microprocessor or multi-core processors that execute software, some implementations are performed by one or more integrated circuits, for example application specific integrated circuits (ASICs) or field programmable gate arrays (FPGAs). In some implementations, such integrated circuits execute instructions that are stored in the circuit itself.

As used in this specification and any claims of this application, the terms “computer”, “server”, “processor”, and “memory” all refer to electronic or other technological devices. These terms exclude people or groups of people. For the purpose of the specification, the terms display or displaying means displaying on an electronic device. As used in this specification and any claims of this application, the terms “computer-readable media” and “computer readable medium” are entirely restricted to tangible, physical objects that store information in a form that is readable by a computer. These terms exclude any wireless, wired download signals, and any other ephemeral signals.

To provide for interaction with a user, implementations of the subject matter described in this specification can be implemented on a computer having a display device, e.g., a CRT (cathode ray tube) or LCD (liquid crystal display) monitor, or any other available monitor types, for displaying information to the user and a keyboard and a pointing device, e.g., mouse or trackball, by which the user can provide input to the computer. Other kinds of devices can be used to provide for interaction with a user as well; for example, feedback provided to the user can be any form of sensory feedback, e.g., visual feedback, tactile feedback, or auditory feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

The subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication network include a local area network (“LAN”), an inter-network (e.g., the Internet), and peer-to-peer networks (e.g., ad-hoc peer-to-peer networks).

The subject matter described in this specification can be implemented using client-side applications, web pages, mobile web pages, or other software as generally known in the art and that would be usable to end-user customers (for community self-managed RAN apps) and/or mobile operator end users. The subject matter could alternately be delivered or implemented using an API, such as a SOAP API, a JSON API, a RESTful API, in lieu of or in conjunction with a direct end-user interface. The subject matter could use messaging queues, webhooks, server-side containers, or any other technology known in the art.

The computing system can include clients and servers. A client and server are generally remote from each other and typically interact through a communication network. The relationship of client and server arises by virtue of computer programs running on the respective computers and having a client-server relationship to each other. In some aspects of the disclosed subject matter, a server transmits data (e.g., an HTML page) to a client device (e.g., for purpose of displaying data to and receiving user input from a user interacting with the client device). Data generated at the client device (e.g., a result of the user interaction) can be received from the client device at the server. Any database could be used (SQL, NoSQL, temporal, key-value, etc.). Any container orchestration technology (Kubernetes, Docker Swarm) could be used.

Various modifications to these aspects will be readily apparent, and the generic principles defined herein may be applied to other aspects. Thus, the claims are not intended to be limited to the aspects shown herein, but is to be accorded the full scope consistent with the language claims, where reference to an element in singular is not intended to mean “one and only one” unless specifically so states, but rather “one or more.” Unless expressly stated otherwise, the term “some” refers to one or more. Pronouns in the masculine (e.g., his) include the feminine and neuter gender (e.g., her and its) and vice versa. Headings and subheadings, if any, are used for convenience only, and do not limit the subject technology.

A phrase, for example, an “aspect” does not imply that the aspect is essential to the subject technology or that the aspect applies to all configurations of the subject technology. A disclosure relating to an aspect may apply to all configurations, or one or more configurations. A phrase, for example, an aspect may refer to one or more aspects and vice versa. A phrase, for example, a “configuration” does not imply that such configuration is essential to the subject technology or that such configuration applies to all configurations of the subject technology. A disclosure relating to a configuration may apply to all configurations or one or more configurations. A phrase, for example, a configuration may refer to one or more configurations and vice versa.

The foregoing discussion discloses and describes merely exemplary embodiments of the present invention. In some embodiments, software that, when executed, causes a device to perform the methods described herein may be stored on a computer-readable medium such as a computer memory storage device, a hard disk, a flash drive, an optical disc, or the like. As will be understood by those skilled in the art, the present invention may be embodied in other specific forms without departing from the spirit or essential characteristics thereof. For example, cloud topology could vary and public and private cloud services could be mixed; certain services could be provided by containers while other services could be provided by dedicated machines or virtual machines or virtual network functions (for example, a data sink could be a traditional billing server); wireless network topology can also apply to wired networks, optical networks, and the like; etc. The methods may apply to LTE-compatible networks, to UMTS-compatible networks, or to networks for additional protocols that utilize radio frequency data transmission. Various components in the devices described herein may be added, removed, or substituted with those having the same or similar functionality. Various steps as described in the figures and specification may be added or removed from the processes described herein, and the steps described may be performed in an alternative order, consistent with the spirit of the invention. Accordingly, the disclosure of the present invention is intended to be illustrative of, but not limiting of, the scope of the invention, which is specified in the following claims.

What is claimed is:

1. A system for cooling of telecommunications equipment, comprising:
a nozzle disposed proximate a piece of telecommunication equipment to be cooled;
a fluid conduit in fluid communication with the nozzle;
a fluid supply coupled to the fluid conduit and providing fluid to the fluid nozzle; and
a nozzle control system configured to actuate the nozzle to cause fluid to emerge from the nozzle, thereby providing a fluid mist to cool the air surrounding at least a part of the telecommunication equipment.

2. The system of claim 1 wherein the fluid comprises a gas or a liquid.

3. The system of claim 1 wherein the telecommunication equipment comprises a base station.

4. The system of claim 1 further comprising a fluid pump disposed between the fluid supply and the fluid conduit for moving the fluid from the supply to the nozzle via the fluid conduit.

5. The system of claim 5 wherein the fluid pump is solar powered.

6. The system of claim 1 wherein the fluid supply comprises a fluid storage tank.

7. The system of claim 6 wherein the fluid storage tank is disposed underground

8. The system of claim 1 wherein the nozzle control system comprises a microcontroller based control system, a base station based control system or an Internet of things (IoT) device based control system.

9. The system of claim 1 wherein the nozzle control system is controlled based on time of day, radio usage, Central Processor Unit (CPU) usage, power usage, predicted power usage, measured outdoor temperature, measured telecommunication equipment temperature, data analytics, observed statistical patterns or predicted statistical patterns.

10. The system of claim 1 where the misting shape and pressure is software controlled.

11. The system of claim 1 further comprising a cooling device disposed between the fluid supply and nozzle to cool the fluid before the fluid is emitted by the nozzle.

12. The system of claim 1 further comprising:
a telecommunications mast having a radio antenna disposed thereon, wherein the fluid conduit is located below the radio antenna and above the piece of telecommunication equipment to be cooled, the fluid conduit, the radio antenna and the piece of telecommunication equipment to be cooled in mechanical communication with the telecommunications mast.

13. The system of claim 9 wherein the power usage is predicted by a controller node and instructions to operate the nozzle control system based on the power usage are sent to a base station, the base station comprising the telecommunications equipment to be cooled.

14. The system of claim 9 wherein the power usage is measured at the telecommunications equipment to be cooled and sent to a controller node.

15. A system for cooling of telecommunications equipment, comprising:
a ring of tubing, positioned below at least one radio antenna and above a radio device to be cooled, the ring of tubing and the at least one radio antenna and the radio device to be cooled being affixed to a telecommunications mast;
a sprinkler physically coupled to the ring of tubing and configured to receive water from the ring of tubing;
a sprinkler control system configured to actuate the sprinkler to cause water to emerge from the sprinkler, thereby creating mist in the vicinity of the radio device to be cooled; and
a water supply coupled to the ring of tubing and located in a location protected from solar heating.
